(19) United States
(12) Patent Application Publication
(10) Pub. No.: US 2015/0050596 A1
(43) Pub. Date: Feb. 19, 2015

(54) PHOTOSENSITIVE POLYSILOXANE COMPOSITION AND USES THEREOF

(71) Applicant: CHI MEI CORPORATION, TAINAN CITY (TW)

(72) Inventors: MING-JU WU, TAINAN CITY (TW); CHUN-AN SHIH, TAINAN CITY (TW)

(21) Appl. No.: 14/448,645

(22) Filed: Jul. 31, 2014

(30) Foreign Application Priority Data
Aug. 13, 2013 (TW) 102128929

(51) Int. Cl. G03F 7/075; G03F 7/16

(52) U.S. Cl. CPC G03F 7/0757; G03F 7/16
USPC 430/287.1

(57) ABSTRACT

The invention relates to a photosensitive polysiloxane composition and a thin film formed by the aforementioned photosensitive polysiloxane composition. The thin film is a planarization film of a TFT substrate, an interlayer insulating film or an overcoat of a core material or a protective material in a waveguide. The photosensitive polysiloxane composition has excellent chemical resistance. The photosensitive polysiloxane composition comprises a polysiloxane (A), an o-naphthoquinone diazide sulfonic acid ester (B), a thermal base generator (C) and a solvent (D).

### BACKGROUND OF THE INVENTION

1. Field of the Invention

The invention relates to a photosensitive polysiloxane composition and a thin film and device formed by the aforementioned photosensitive polysiloxane composition. The thin film is a planarization film of a TFT substrate in a liquid crystal display element or organic light-emitting display device, an interlayer insulating film or an overcoat of a core material or a protective material in a waveguide. More particularly, the invention is to provide a photosensitive polysiloxane composition having excellent chemical resistance after exposing and developing.

2. Description of the Related Art

In recent years, in the field of the semiconductor industry, liquid crystal displays (LCDs) and organic electro-luminescence displays (OELDs), with the size reduction, the demand of the miniaturization of the pattern(s) in the photolithography process is increased. Generally, the miniaturized pattern is formed by exposing and developing a positive photosensitive composition having high resolution and high photosensitivity; wherein, a positive photosensitive composition using a polysiloxane as the main component has become the mainstream in this field.

Japanese Patent Publication No. 2008-107529 discloses a photosensitive composition for a curing film of a high degree of transparency. The photosensitive composition uses a polysiloxane comprising oxetanyl or oxydicarbonyl groups, which form a hydrophilic structure through a ring-opening reaction in a copolymerization. Although the photosensitive composition has high solubility in a weak alkaline developer, the poor chemical resistance of the photosensitive composition can not be accepted in this field.

Therefore, a photosensitive polysiloxane composition that enhances the chemical resistance at the same time is a target remained to be achieved.

### SUMMARY OF THE INVENTION

In the present invention, a specific polysiloxane and thermal base generator are provided to obtain a photosensitive polysiloxane composition having good chemical resistance.

Therefore, the invention relates to a photosensitive polysiloxane composition comprising:

a polysiloxane (A);

an o-naphthoquinone diazide sulfonic acid ester (B);

a thermal base generator (C); and

a solvent (D);

wherein:

the thermal base generator (C) comprises a compound represented by Formula (1) or an salt derivative thereof and/or a compound represented by Formula (2) and/or a compound represented by Formula (3):

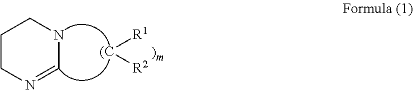

wherein:

m represents an integer selected from 2 to 6;

R¹ and R² independently represent a hydrogen atom, a C₁-C₈ alkyl group, a substituted or unsubstituted C₁-C₆ hydroxyalkyl group, or a C₂-C₁₂ dialkylamino group;

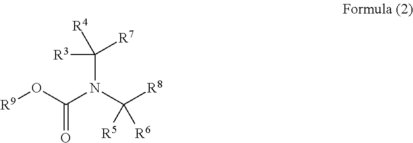

wherein:

R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;

R⁷ and R⁸ independently represent a hydrogen atom, a substituted or unsubstituted C₁-C₈ alkyl group, a substituted or unsubstituted C₃-C₈ cylcoalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group; the total carbon atom amount of R⁷ and R⁸ are below 10;

R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12.

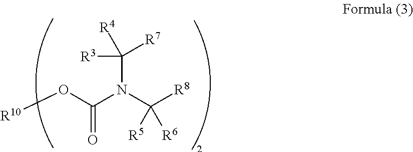

wherein:

R³, R⁴, R⁵, R⁶, R⁷ and R⁸ are as defined in Formula (2);

R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsbustituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

The present invention also provides a method for forming a thin film on a substrate comprising applying the photosensitive polysiloxane composition as mentioned above on the substrate.

The present invention also provides a thin film on a substrate, which is manufactured by the method as mentioned above.

The present invention further provides an device comprising the thin film as mentioned above.

### DETAILED DESCRIPTION OF THE INVENTION

The invention relates to a photosensitive polysiloxane composition comprising:

a polysiloxane (A);

an o-naphthoquinone diazide sulfonic acid ester (B);

a thermal base generator (C); and

a solvent (D);

wherein:

the thermal base generator (C) comprises a compound represented by Formula (1) or an salt derivative thereof and/or a compound represented by Formula (2) and/or a compound represented by Formula (3):

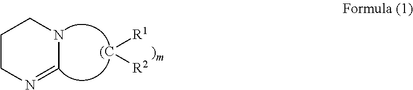

wherein:

m represents an integer selected from 2 to 6;

R¹ and R² independently represent a hydrogen atom, a C₁-C₈ alkyl group, a substituted or unsubstituted C₁-C₆ hydroxyalkyl group, or a C₂-C₁₂ dialkylamino group;

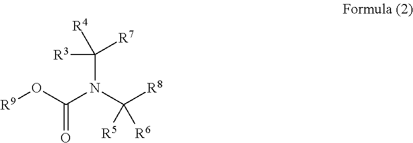

wherein:

R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;

R⁷ and R⁸ independently represent a hydrogen atom, a substituted or unsubstituted C₁-C₈ alkyl group, a substituted or unsubstituted C₃-C₈ cylcoalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group; the total carbon atom amount of R⁷ and R⁸ are below 10;

R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12.

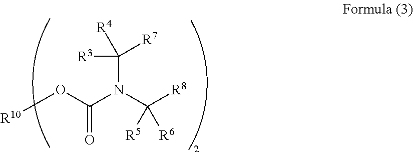

wherein:

R³, R⁴, R⁵, R⁶, R⁷ and R⁸ are as defined in Formula (2);

R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsbustituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

The kind of the polysiloxane (A) is not particularly limited, as long as the purpose of the present invention can be fulfilled. Preferably, the polysiloxane (A) is a copolymer obtained by hydrolyzing and partial condensing a silane monomer component represented by Formula (4);

Si(Rₐ)_{W}(OR_{b})_{4-w} Formula (4),

wherein:

at least one of Rₐ represents an alkyl group substituted with an acid anhydride group, an alkyl group substituted with an epoxy group or an alkoxy group substituted with an epoxy group; other Rₐ represents a hydrogen atom, a C₁-C₁₀ alkyl group, a C₂-C₁₀ alkenyl group, a C₆-C₁₅ aryl group; each Rₐ is the same or different;

R_{b} represents a hydrogen atom, a C₁-C₆ alkyl group, a C₁-C₆ acyl group, a C₆-C₁₅ aryl group; each R_{b} is the same or different; and

w represents an integer from 0 to 3.

The C₁-C₁₀ alkyl group substituted with the acid anhydride group, for example, is ethyl succinic anhydride, propyl succinic anhydride or propyl glutaric anhydride

The C₁-C₁₀ alkyl group substituted with the epoxy group, for example, is oxetanylpentyl or 2-(3,4-epoxycyclohexyl)ethyl).

The alkoxy group substituted with the epoxy group, for example, is glycidoxypropy or 2-oxetanylbutoxy.

In the definition of R_{b}, the C₁-C₆ alkyl group includes but is not limited to methyl, ethyl, n-propyl, isopropyl or n-butyl. The C₁-C₆ acyl group includes but is not limited to acetyl. The C₆-C₁₅ aryl group includes but is not limited to phenyl.

A silane monomer represented by Formula (4) can be used singly or in combination, and the silane monomer represented by Formula (4) includes but is not limited to 3-glycidoxypropyltrimethoxysilane (abbreviated as TMS-GAA), 3-glycidoxypropyltriethoxysilane, 2-(3,4-epoxycyclohexyl)ethyl trimethoxy silane, 2-oxetanylbutoxypropyltriphenoxysilane), the commercially available products from Toagosei Co., Ltd.: 2-oxetanylbutoxypropyltrimethoxysilane (trade name: TMSOX-D), 2-oxetanylbutoxypropyltriethoxysilane (trade name: TESOX-D), 3-triphenoxysilyl propyl succinic anhydride, the commercially available products from Shin-Etsu Chemical Co., Ltd.: 3-trimethoxysilyl propyl succinic anhydride (trade name: X-12-967), the commercially available products from WACKER Co., Ltd: 3-(triethoxysilyl)propyl succinic anhydride (trade name: GF-20), 3-(trimethoxysilyl)propyl glutaric anhydride (abbreviated as TMSG), 3-(triethoxysilyl)propyl glutaric anhydride, 3-(triphenoxysilyl)propyl glutaric anhydride, diisopropoxy-di(2-oxetanylbutoxy propyl)silane (abbreviated as DIDOS), di(3-oxetanylpentyl)dimethoxy silane, (di-n-butoxysilyl)di(propyl succinic anhydride), (dimethoxysilyl)di(ethyl succinic anhydride), 3-glycidoxypropyldimethylmethoxysilane, 3-glycidoxypropyldimethylethoxysilane, di(2-oxetanylbutoxypentyl)-2-oxetanylpentylethoxy silane, tri(2-oxetanylpentyl)methoxy silane, (phenoxysilyl)tri(propyl succinic anhydride) or (methoxysilyl)di(ethyl succinic anhydride).

Preferably, the silane monomer component also comprises a silane monomer represented by Formula (4-1).

Si(R_{c})ᵤ(OR_{d})₄₋ᵤ Formula (4-1)

In Formula (4-1), u represents an integer from 0 to 3; R_{c} represents hydrogen, a C₁-C₁₀ alkyl group, a C₂-C₁₀ alkenyl group, or a C₆-C₁₅ aryl group, and each R_{c} is the same or different; R_{d} represents hydrogen, a C₁-C₆ alkyl group, a C₁-C₆ acyl group, or a C₆-C₁₅ aryl group, and each R_{d} is the same or different.

In the definition of R_{c}, the C₁-C₁₀ alkyl group, for example, is methyl, ethyl, n-propyl, isopropyl, n-butyl, tertiary butyl, n-hexyl, n-decyl, trifluoromethyl, 3,3,3-trifluoro-propyl, 3-aminopropyl, 3-mercaptopropyl or 3-isocyanatepropyl. The C₂-C₁₀ alkenyl group, for example, is vinyl, 3-acryloxypropyl or 3-methacryloxypropyl. The C₆-C₁₅ aryl group, for example, is phenyl, tolyl, o-hydroxyphenyl, 1-(o-hydroxyphenyl)ethyl, 2-(o-hydroxyphenyl)ethyl, 4-hydroxy-5-(p-hydroxyphenylcarbonyloxy)pentyl or naphthyl.

In the definition of R_{d}, the C₁-C₆ alkyl group, for example, is methyl, ethyl, n-propyl, isopropyl, or n-butyl. The C₁-C₆ acyl group, for example, is acetyl. The C₆-C₁₅ aryl group, for example, is phenyl.

A silane monomer represented by Formula (4-1) can be used singly or in combination, and the silane monomer represented by Formula (4-1) includes but is not limited to tetramethoxysilane, tetraethoxysilane, tetraacetoxysilane, tetraphenoxy silane, methyltrimethoxysilane (abbreviated as MTMS), methyltriethoxysilane, methyltriisopropoxysilane, methyl-tri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, phenyltrimethoxysilane (abbreviated as PTMS), phenyltriethoxysilane (abbreviated as PTES), p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, dimethyldimethoxysilane (abbreviated as DMDMS), dimethyldiethoxysilane, dimethyldiacetyloxysilane, di-n-butyldimethoxysilane, diphenyldimethoxysilane, trimethylmethoxysilane, tri-n-butylethoxysilane, 3-mercaptopropyltrimethoxysilane, 3-acryloxypropyltrimethoxysilane, 3-methacryloyloxypropyltrimethoxysilane, or 3-methacryloyloxypropyltriethoxysilane.

Preferably, the silane monomer component also comprises a polysiloxane represented by Formula (4-2).

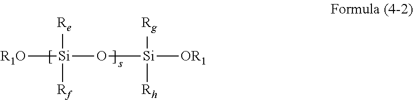

In Formula (4-2), each Rₑ, R_{f}, R_{g} and Rₕ are the same or different, and each independently represents a hydrogen atom, a C₁-C₁₀ alkyl group, a C₂-C₆ alkenyl group, or a C₆-C₁₅ aryl group. It is noted that any one of the above alkyl group, alkenyl group and aryl group can optionally have a substituent. When s is an integer from 2 to 1000, each Rₑ is the same or different, and R_{f} is the same or different. The alkyl group, for example, is methyl, ethyl or n-propyl; the alkenyl group, for example, is vinyl, acryloyl-propyl or methyl-acryloyloxy-propyl; the aryl group, for example, is phenyl, tolyl, or naphthyl.

R_{f}, and R_{g} independently represent a hydrogen atom, a C₁-C₆ alkyl group, a C₁-C₆ acyl group, or a C₆-C₁₅ aryl group. It is noted that any one of the above alkyl group, acyl group and aryl group can optionally have a substituent. The alkyl group, for example, is methyl, ethyl, n-propyl, isopropyl, or n-butyl.; the acyl group, for example, is acetyl; the aryl group, for example, is phenyl.

In Formula (4-2), s is an integer selected from 1 to 1000; preferably s is an integer selected from 3 to 300; more preferably s is an integer selected from 5 to 200.

The polysiloxane represented by Formula (4-2) can be used singly or in combination. The polysiloxane represented by Formula (4-2) includes but is not limited to 1,1,3,3-tetramethyl-1,3-dimethoxy disiloxane, 1,1,3,3-tetramethyl-1,3-diethoxy disiloxane, 1,1,3,3-tetraethyl-1,3-diethoxy disiloxane or the commercially available products of silanol terminated polydimethylsiloxane manufactured by Gelest Company (trade names such as DM-S12 (molecular weight of 400 to 700), DMS-S15 (molecular weight of 1500 to 2000), DMS-S21 (molecular weight 4200), DMS-S27 (molecular weight 18000), DMS-S31 (molecular weight 26000), DMS-S32 (molecular weight 36000), DMS-S33 (molecular weight 43500), DMS-S35 (molecular weight 49000), DMS-S38 (MW 58000) DMS-S42 (molecular weight 77000) or PDS-9931 (MW 1000-1400)).

Preferably, the silane monomer component also includes silicon dioxide particles. The average particle diameter of the silicon dioxide particles is not particularly limited and ranges from 2 nm to 250 nm, preferably from 5 nm to 200 nm, and more preferably from 10 nm to 100 nm

The silicon dioxide particles can be used singly or in combination, and the silicon dioxide particles include but are not limited to commercially available products manufactured by Jgc Catalysts & Chemicals Co., Ltd. [trade names: Oscar 1132 (particle diameter of 12 nm; dispersing agent is methanol), OSCAR 1332 (particle diameter of 12 nm; dispersant n-propanol), OSCAR 105 (particle size 60 nm; dispersant y-butyrolactone), OSCAR 106 (particle diameter of 120 nm; dispersant diacetone alcohol), etc.]; commercially available products by Fuso Chemical Co. [ trade names: Quartron PL-1-IPA (particle diameter of 13 nm; dispersant isobutyl ketone), Quartron PL-1-TOL (particle diameter of 13 nm; dispersant toluene), Quartron PL-2L-PGME (18 nm particle size; diacetone alcohol propylene glycol monomethyl ether) or Quartron PL-2L-MEK (particle size 18 nm; dispersant methyl ethyl ketone)]; or commercially available products manufactured by Nissan Chemical Company [trade names, such as IPA-ST (particle diameter 12 nm; dispersant isopropanol), EG-ST (particle diameter of 12 nm; dispersant ethylene glycol), IPA-ST-L (particle size 45 nm; dispersant isopropanol) or IPA-ST-ZL (particle diameter of 100 nm; dispersant isopropyl alcohol)].

A general method can be applied in the condensation reaction, for example, adding solvents, water and optionally catalyst in the silane monomer component, and heating and stirring under 50° C. to 150° C. for 0.5 to 120 hours, and removing byproducts (alcohols, water, etc.) by distillation with stirring.

The solvent used in the aforementioned reaction is not particularly limited, and the solvent can be the same or different from the solvent (D) included in the photosensitive polysiloxane composition according to the present invention. Based on 100 parts by weight of the total used amount of the silane monomer component, the used amount of the solvent is from 15 to 1200 g; preferably from 20 to 1100 g; and more preferably from 30 to 1000 g.

Based on 1 mole of hydrolyzable groups contained in the silane monomer component, the used amount of the water in the aforementioned reaction is from 0.5 moles to 2 moles.

The catalyst is not particularly limited, and is preferably selected from the group consisting of an acidic catalyst and a basic catalyst. The acidic catalyst includes but is not limited to hydrochloric acid, nitric acid, sulfuric acid, hydrofluoric acid, oxalic acid, phosphoric acid, acetic acid, trifluoroacetic acid, formic acid, polybasic carboxylic acid or an anhydride thereof, or ion exchange resins. The basic catalyst includes but is not limited to diethylamine, triethylamine, tripropylamine, tributylamine, tripentylamine, trihexylamine, triheptylamine, trioctylamine, diethanolamine, triethanolamine, sodium hydroxide, and potassium hydroxide, the amine group-containing silane having an alkoxy group or ion exchange resins and the like.

Based on 100 parts by weight of the total used amount of the silane monomer component, the used amount of the catalyst in the aforementioned reaction preferably is from 0.005 g parts by weight to 15 g parts by weight; more preferably 0.01 g parts by weight to 12 g parts by weight; and most preferably from 0.05 g parts by weight to 10 g parts by weight.

Concerning stability, the polysiloxane (A) manufactured by the condensation reaction preferably excludes the byproducts (such as alcohols or water) and the catalyst. Therefore the polysiloxane (A) can be optionally purified. The purification method is not particularly limited. Preferably, a hydrophobic solvent is used for the dilution of the polysiloxane (A). Subsequently, the organic layer is washed with water several times and concentrated by a rotary evaporator to remove the alcohols or water. In addition, ion exchange resins can be used to remove the catalyst.

In the present invention, if the alkyl group containing the acid anhydride group, the alkyl group containing the epoxy group or the alkoxy group containing the epoxy group is absent in the polysiloxane (A), the chemical resistance is poor. Though not willing to be limited by theory, it is believed that because the acid anhydride group and the epoxy group have excellent reactivity, they can form a bridge between macromolecules and form a net which has good density and chemical resistance.

The kind of the o-naphthoquinone diazide sulfonic acid ester (B) according to the present invention is not particularly limited, and common o-naphthoquinone diazide sulfonic acid esters can be used. The o-naphthoquinone diazide sulfonic acid ester (B) can be completely esterified or partially esterified ester-based compound.

The O-naphthoquinone diazide sulfonic acid ester (B) is preferably prepared by reacting an o-naphthoquinone diazide sulfonic acid or salts thereof with a hydroxy compound. The O-naphthoquinone diazide sulfonic acid ester (B) is more preferably prepared by reacting the o-naphthoquinone diazide sulfonic acid or salts thereof with a polyhydroxy compound.

The O-naphthoquinone diazide sulfonic acid is, for example, o-naphthoquinone diazide-4-sulfonic acid, o-naphthoquinone diazide-5-sulfonic acid or o-naphthoquinone diazide-6-sulfonic acid. In addition, the o-naphthoquinone diazide sulfonic acid salts are, for example, o-naphthoquinone diazonaphthoquinone sulfonyl halides.

The hydroxy compound is, for example:

(1) Hydroxybenzophenone-based compounds, such as, 2,3,4-trihydroxy-benzophenone, 2,4,4′-trihydroxy-benzophenone, 2,4,6-trihydroxy-benzophenone, 2,3,4,4′-tetrahydroxy benzophenone, 2,4,2′,4′-tetrahydroxy benzophenone, 2,4,6,3′,4′-pentahydroxy-benzophenone, 2,3,4,2′,4′-pentahydroxy-benzophenone, 2,3,4,2′,5′-pentahydroxy-benzophenone, 2,4,5,3′,5′-pentahydroxy-benzophenone or 2,3,4,3′,4′,5′-hexahydroxy-benzophenone.

(2) Hydroxyaryl-based compounds, for example, a hydroxy aryl compound represented by Formula (5-1):

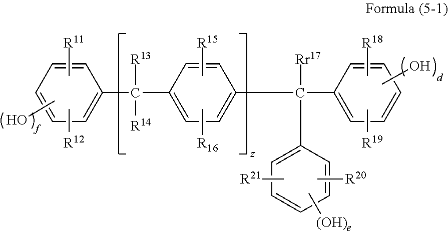

in Formula (5-1), wherein, each R¹¹ and R¹² independently represents a hydrogen atom, a halogen atom or a C₁-C₆ alkyl group; each R¹³, R¹⁴, R¹⁷ independently represents a hydrogen atom or a C₁-C₆ alkyl group; each R¹⁵, R¹⁶, R¹⁸, R¹⁹, R²⁰ and R²¹ independently represents a hydrogen atom, a halogen atom, a C₁-C₆ alkyl group, a C₁-C₆ alkoxy group, a C₁-C₆ alkenyl group or a C₁-C₆ cycloalkyl group; each d, e and f independently represents an integer selected from 1 to 3; z represents 0 or 1.

The hydroxyaryl-based compounds represented in Formula (5-1) are, for example, tris(4-hydroxyphenyl)methane, bis(4-hydroxy-3,5-dimethyl-phenyl)-4-hydroxyphenyl methane, bis(4-hydroxy-3,5-dimethyl-phenyl)-3-hydroxyphenyl methane, bis(4-hydroxy-3,5-dimethyl-phenyl)-2-hydroxyphenyl methane, bis(4-hydroxy-2,5-dimethylphenyl)-4-hydroxyphenyl methane, bis(4-hydroxy -2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-bis(hydroxyphenyl)methane, bis(4-hydroxy-2,5-dimethylphenyl)-3,4-dihydroxyphenyl methane, bis(4-hydroxy-3,5-dimethylphenyl)-2,4-hydroxyphenyl methane, bis(4-hydroxy-2,5-dimethylphenyl)-2,4-dihydroxyphenyl methane, bis(4-hydroxyphenyl)-3-methoxy-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-methyl-phenyl)-2-hydroxyphenyl methane, bis(3-cyclohexyl-4-hydroxy-6-methyl-phenyl)-3-hydroxyphenyl methane, bis(3-cyclohexyl-4-hydroxy-6-methylphenyl)-4-hydroxyphenyl methane, bis(3-cyclohexyl-4-hydroxy-6-methyl-phenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methyl-phenyl)-3,4-dihydroxyphenyl methane, 1-[1-(4-hydroxyphenyl)isopropyl]-4-[1,1-bis(4-hydroxyphenyl) ethyl]benzene or 1-[1-(3-methyl-4-hydroxyphenyl)isopropyl]-4-[1,1-bis(3-methyl-4-hydroxyphenyl)ethyl]benzene.

(3) (Hydroxyphenyl) hydrocarbon compounds, for example, (hydroxyphenyl) hydrocarbon compounds represented by Formula (5-2):

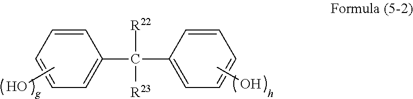

wherein in Formula (5-2), each R²² and R²³ independently represents a hydrogen atom or a C₁-C₆ alkyl group; each g and h independently represents an integer selected from 1 to 3.

The (hydroxyphenyl)-hydrocarbon compounds represented in Formula (5-2) are, such as, 2-(2,3,4-trihydroxyphenyl)-2-(2′,3′,4′-trihydroxyphenyl)propane, 2(2,4-dihydroxyphenyl)-2-(2′,4′-dihydroxyphenyl)propane, 2-(4-hydroxyphenyl)-2-(4′-hydroxyphenyl)propane, bis(2,3,4-trihydroxyphenyl)methane or bis(2,4-dihydroxyphenyl)methane and the like.

(4) Other aromatic hydroxyl compounds are, such as phenol, p-methoxyphenol, dimethylphenol, hydroquinone, bisphenol A, naphthol, catechol, 1,2,3-pyrogallol methyl ether, 1,2,3-pyrogallol-1,3-dimethyl ether, 3,4,5-trihydroxy benzoic acid, or partially esterified or etherified 3,4,5-trihydroxy benzoic acid.

The hydroxy compound is preferably 1-[1-(4-hydroxyphenyl)isopropyl]-4-[1,1-bis(4-hydroxyphenyl)ethyl]benzene, 2,3,4-trihydroxy-benzophenone, 2,3,4,4′-tetrahydroxy benzophenone, or a combination thereof. The hydroxy compounds can be used singly or in combination.

The reaction of the o-naphthoquinone diazide sulfonic acid or salts thereof with the hydroxy compound is usually performed in an organic solvent, such as dioxane, N-pyrrolidone, acetamides and etc. Furthermore, the reaction is preferably performed in an alkaline condensing agent, such as triethanolamine, alkali metal carbonates or alkali metal bicarbonates.

The degree of esterification of the o-naphthoquinone diazide sulfonic acid ester (B) is preferably more than 50%. That is, based on 100 mol % of the used amount of the hydroxyl groups in the hydroxy compound, 50 mole % or more hydroxyl groups in the hydroxy compound react with the o-naphthoquinone diazide sulfonic acid or salts thereof in the esterification reaction. The degree of esterification of the o-naphthoquinone diazide sulfonic acid ester (B) is more preferably 60% or more.

Based on 100 parts by weight of the used amount of the polysiloxane (A), the used amount of the o-naphthoquinone diazide sulfonic acid ester (B) is from 1 part by weight to 30 parts by weight; preferably 3 parts by weight to 25 parts by weight; and more preferably 5 parts by weight to 20 parts by weight.

The thermal base generator (C) according to the present invention comprises a compound represented by Formula (1) or an salt derivative thereof and/or a compound represented by Formula (2) and/or a compound represented by Formula (3):

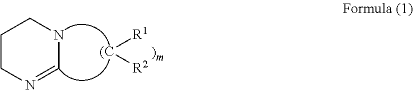

wherein:

m represents an integer selected from 2 to 6; and

R¹ and R² independently represent a hydrogen atom, a C₁-C₈ alkyl group, a substituted or unsubstituted C₁-C₆ hydroxyalkyl group, or a C₂-C₁₂ dialkylamino group;

preferably, m represents an integer selected from 3 to 5.

In one embodiment of the invention, R¹ and R² independently represent a hydrogen atom; a C₁-C₈ alkyl group, for example: methyl, ethyl, isopropyl, n-butyl, tert-butyl or n-hexyl; a substituted or unsubstituted C₁-C₆ hydroxyalkyl group, for example: hydroxymethyl, 2-hydroxyethyl, 2-hydroxypropyl, 2-hydroxy isopropyl, 3-hydroxy-tert-butyl or 6-hydroxyhexyl; a C₂-C₁₂ dialkylamino group, for example: dimethylamino, methylethylamino, diethylamino, di-isopropylamino, tert-butyl-methylamino or di-n-hexylamino.

The preferred examples of the aforementioned compound represented by Formula (1) or the salt derivative thereof are 1,5-diazabicyclo[4.3.0]non-5-ene (DBN), 1,5-diazabicyclo[4.4.0]dec-5-ene, 1,8-diazabicyclo[5.4.0]undec-7-ene (DBU), 5-hydroxypropyl-1,8-diazabicyclo[5.4.0]undec-7-ene, 5-dibutylamino-1,8-diazabicyclo[5.4.0]undec-7-ene or the commercially available products manufactured by Aporo Co., Ltd.: U-CAT® SA810, U-CAT® SA831, U-CAT® SA841, U-CAT® SA851, U-CAT® 5002; more preferably, DBN, U-CAT® SA851 or U-CAT® 5002.

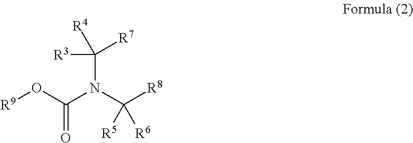

wherein:

R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;

R⁷ and R⁸ independently represent a hydrogen atom, a substituted or unsubstituted C₁-C₈ alkyl group, a substituted or unsubstituted C₃-C₈ cylcoalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group;

R⁹ represents a substituted or unsubstituted C₁-C ₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12.

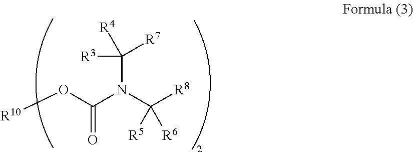

wherein:

R³, R⁴, R⁵, R⁶, R⁷ and R⁸ are as defined in Formula (2);

R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsbustituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

The preferred examples of the aforementioned compounds represented by Formula (2) and Formula (3) are N-(isopropoxycarbonyl)-2,6-dimethyl piperidine, N-(isopropoxycarbonyl)-2,2,6,6-tetramethyl piperidine, N-(isopropoxycarbonyl)diisopropylamine, N-(isopropoxycarbonyl) pyrrolidine, N-(isopropoxycarbonyl)-2,5-dimethyl pyrrolidine, N-(isopropoxycarbonyl)azetidine, N-(1-ethylpropoxycarbonyl)-2,6-dimethyl piperidine, N-(1-ethylpropoxycarbonyl)-2,2,6,6-tetramethyl piperidine, N-(1-ethylpropoxycarbonyl)diisopropylamine, N-(1-ethylpropoxycarbonyl)pyrrolidine, N-(1-ethylpropoxycarbonyl)-2,5-dimethyl pyrrolidine, N-(1-ethylpropoxycarbonyl)azetidine, N-(1-propylbutoxycarbonyl)-2,6-dimethyl piperidine, N-(1-propylbuloxycarbonyl)-2,2,6.6-tetramethyl piperidine, N-(1-propylbutoxcarbonisopropylamine, N-(1-propylbutoxarbonyl)pyrrolidine, N-(1-propylbutoxycarbonyl)-2,5-dimethyl pyrrolidine, N-(1-propylbutoxycarbonyl)azetidine, N-(cyclopenlyloxycarbonyl)-6-dimethyl piperidine, N-(cyclopentyloxycarbonyl)-2,2,6,6-tetramethyl piperidine, N-(cyclopentloxycarbonyl)diisopropylamine, N-(cyclopentyloxycarbonyl)pyrrolidine, N-(cyclopentyloxycarbonyl)-2,5-dimethyl pyrrolidine, N-(cyclopentyloxycarbonyl)azetidine, N-(cyclohexylcarbonyl)-2,6-dimethyl piperidine, N-(cyclohexylcarbonyl)-2,2,6,6-tetramethyl piperidine, N-(cyclohexylcarbonyl)diisopropylamine, N-(cyclohexylcarhonyl)pyrrolidine, (cyclohexylcarbonyl)-2,5-dimethyl pyrrolidine, N-(cyclohexylcarbonyl)azetidine, N-(tert-butoxycarbonyl)-2,6-dimethyl piperidine, N-(tert-buloxycarbonyl)-2,2,6,6-tetramethyl piperidine, N-(tert-butoxycarbonyl)diisopropylamine, N-(tert-butoxycarbonyl)pyrrolidine, N-(tert-butoxycarbonyl)-2,5-dimethyl pyrrolidine, N-(tert-butoxycarbonyl)azetidine, N-(benzyloxycarbonyl)-2,6-dimethyl piperidine, N-(benzyloxycarbonyl)-2,2,6,6-tetramethyl piperidine, N-(benzyloxycarbonyl)diisopropylamine, N-(benzyloxycarbonyl)pyrrolidine, N-(benzyloxycarbonyl)-2,5-dimethyl pyrrolidine, N-(benzyloxycarbonyl)azetidin or 1,4-bis(N,N′-diisopropylaminocarbonyl)cyclohexane; preferably N-(isopropoxycarbonyl)-2,6-dimethyl piperidine, N-(1-ethylpropoxycarbonyl)diisopropylamine, (cyclopentyloxycarbonyl)-2,6-dimethyl piperidine, N-(benzyloxycarbonyl)pyrrolidine or 1,4-bis(N,N′-diisopropylaminocarbonyl)cyclohexane.

Based on 100 parts by weight of the used amount of the polysiloxane (A), the used amount of the thermal base generator (C) is from 0.05 parts by weight to 20 parts by weight; preferably from 0.1 parts by weight to 18 parts by weight; and more preferably from 0.1 parts by weight to 15 parts by weight.

If the thermal base generator (C) is absent, the resulted thin film formed has poor chemical resistance. Though not willing to be limited by theory, it is believed that because the thermal base generator (C) can produce a base substance by heating, and it can enhance the cross-linked reaction of the polysiloxane (A) in post-baking by forming a dense net to improve the chemical resistance.

The kind of the solvent (D) according to the present invention is not particularly limited. The solvent (D) is, for example, a compound containing an alcoholic hydroxy group or a cyclic compound containing a carbonyl group.

The compound containing the alcoholic hydroxy group is, for example, acetol, 3-hydroxy-3-methyl-2-butanone, 4-hydroxy-3-methyl-2-butanone, 5-hydroxy-2-pentanone, 4-hydroxy-4-methyl-2-pentanone (also called as diacetone alcohol, DAA), ethyl lactate, butyl lactate, propylene glycol monomethyl ether, propylene glycol monoethyl ether (PGEE), propylene glycol monomethyl ether acetate (PGMEA), propylene glycol mono-n-propyl ether, propylene glycol mono-n-butyl ether, propylene glycol mono-t-butyl ether, 3-methoxy-1-butanol, 3-methyl-3-methoxy-1-butanol or a combination thereof. It is noted that the compound containing the alcoholic hydroxy group is preferably diacetone alcohol, ethyl lactate, propylene glycol monoethyl ether, propylene glycol methyl ether acetate or combinations thereof. The compound containing the alcoholic hydroxy group can be used singly or in combination.

The cyclic compound containing the carbonyl group is, for example, γ-butyrolactone, γ-valerolactone, δ-valerolactone, propylene carbonate, N-methyl pyrrolidone, cyclohexanone or cycloheptanone. It is noted that the cyclic compound containing the carbonyl group is preferably γ-butyrolactone, N-methyl pyrrolidone, cyclohexanone or combinations thereof. The cyclic compound containing the carbonyl group may be used singly or in combination.

The compound containing the alcoholic hydroxy group can be used in combination with the cyclic compound containing the carbonyl group, and the mixing weight ratio of both is not particularly limited. The weight ratio of the compound containing the alcoholic hydroxy group and the cyclic compound containing the carbonyl group ranges preferably from 99/1 to 50/50; more preferably from 95/5 to 60/40. It is noted that when the weight ratio of the compound containing the alcoholic hydroxy group and the cyclic compound containing the carbonyl group is from 99/1 to 50/50 in the solvent (D), the unreacted silanol (Si—OH) groups in the polysiloxane (A) are unlikely to carry on a condensation reaction and storage stability is lowered. In addition, since the compound containing the alcoholic hydroxy group and the cyclic compound containing the carbonyl group have good compatibility with the o-naphthoquinone diazide sulfonic acid ester (B), a whitening phenomenon hardly occurs in the coating film and the transparency of the thin film can be maintained.

Without lowering the effect of the present invention, other solvents can be included. These other solvents can be, for example: (1) esters: ethyl acetate, n-propyl acetate, iso-propyl acetate, n-butyl acetate, isobutyl acetate, propylene glycol monomethyl ether acetate, 3-methoxy-1-butyl acetate or 3-methyl-3-methoxy-1-butyl acetate, etc.; (2) ketones: methyl isobutyl ketone, diisopropyl ketone, or di-isobutyl ketone, etc.; or (3) ethers: diethyl ether, diisopropyl ether, di-n-butyl ether or diphenyl ether etc.

Based on 100 parts by weight of the used amount of the polysiloxane (A), the used amount of the solvent (D) is from 100 parts by weight to 1200 parts by weight; preferably from 150 parts by weight to 1000 parts by weight; and more preferably from 200 parts by weight to 800 parts by weight.

The photosensitive polysiloxane composition of the present invention can optionally further include an additive (E). The additive (E) can be, for example, a sensitizer, adhesion auxiliary agent, surfactant, dissolution promoter, defoamer, or combinations thereof.

The kind of the sensitizer is not particularly limited. The sensitizer can use preferably a compound containing a phenolic hydroxyl group, for example:

(1) a trisphenol type compound: such as tris(4-hydroxyphenyl)methane, bis(4-hydroxy-3-methylphenyl)-2-hydroxyphenyl methane, bis(4-hydroxy-2,3,5-trimethylphenyl)-2-hydroxyphenyl methane, bis(4-hydroxy-3,5-dimethylphenyl)-4-hydroxyphenyl methane, bis(4-hydroxy-3,5-dimethylphenyl)-3-hydroxyphenyl methane, bis(4-hydroxy-3,5-methylphenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-dihydroxyphenyl methane, bis(4-hydroxy-2,5-dimethylphenyl)-3,4-dihydroxyphenyl methane, bis(4-hydroxy-2,5-dimethylphenyl)-2,4-bis(hydroxyphenyl)methane, bis(4-hydroxyphenyl)-3-methoxy-4-hydroxyphenyl methane, bis(5-cyclohexyl-4-hydroxy-2-methylphenyl)-4-hydroxyphenyl methane, bis(5-cyclohexyl-4-hydroxy-2-methylphenyl)-3-hydroxyphenyl methane, bis(5-cyclohexyl-4-hydroxy-2-methylphenyl)-2-hydroxyphenyl methane or bis(5-cyclohexyl-4-hydroxy-2-methylphenyl)-3,4-dihydroxyphenyl methane, etc.;

(2) a bisphenol type compound: such as bis(2,3,4-trihydroxyphenyl)methane, bis(2,4-dihydroxyphenyl)methane, 2,3,4-trihydroxyphenyl-4′-hydroxyphenyl methane, 2-(2,3,4-trihydroxyphenyl)-2-(2′,3′,4′-trihydroxyphenyl) propane, 2-(2,4-dihydroxyphenyl)-2-(2′,4′-dihydroxyphenyl)propane, 2-(4-hydroxyphenyl)-2-(4′-hydroxyphenyl)propane, 2-(3-fluoro-4-hydroxyphenyl)-2-(3′-fluoro-4′-hydroxyphenyl)propane, 2-(2,4-dihydroxyphenyl)-2-(4′-hydroxyphenyl)propane, 2-(2,3,4-trihydroxyphenyl)-2-(4′-hydroxyphenyl)propane or 2-(2,3,4-trihydroxyphenyl)-2-(4′-hydroxy-3′,5′-dimethylphenyl)propane and the like;

(3) a polynuclear branched compounds: such as 1-[1-(4-hydroxyphenyl)isopropyl]-4-[1,1-bis(4-hydroxyphenyl)ethyl]phenyl or 1-[1-(3-methyl-4-hydroxyphenyl)isopropyl]-4-[1,1-bis (3-methyl-4-hydroxyphenyl)ethyl]benzene and the like;

(4) a condensation type phenol compound: such as 1,1-bis(4-hydroxyphenyl)cyclohexane, etc.;

(5) a polyhydroxy benzophenones: such as 2,3,4-trihydroxy benzophenone, 2,4,4′-trihydroxy benzophenone, 2,4,6-trihydroxy benzophenone, 2,3,4-trihydroxy-2′-methylbenzophenone, 2,3,4,4′-tetrahydroxy benzophenone, 2,4,2′,4′-tetrahydroxy benzophenone, 2,4,6,3′,4′-pentahydroxy benzophenone, 2,3,4,2′,4′-pentahydroxy benzophenone, 2,3,4,2′,5′-pentahydroxy benzophenone, 2,4,6,3′,4′,5′-hexahydroxy benzophenone or 2,3,4,3′,4′,5′-hexahydroxy benzophenone; or

(6) combinations of the aforementioned compounds containing the phenolic hydroxyl group.

Based on 100 parts by weight of the used amount of the polysiloxane (A), the used amount of the sensitizer is from 5 parts by weight to 50 parts by weight; preferably from 8 parts by weight to 40 parts by weight; and more preferably from 10 parts by weight to 35 parts by weight.

The adhesion auxiliary agent is, for example, a melamine compound, and a silane-based compound. The role of the adhesion auxiliary agent is to increase the adhesion between the device or component and the thin film that is formed by the photosensitive polysiloxane composition.

Commercially available products of melamine compounds are, for example, manufactured by Mitsui Chemicals, trade names Cymel 300, Cymel-303, etc.; or the products manufactured by Sanwa Chemical, trade names MW-30MH, MW-30, MS-11, MS-001, MX-750 or MX-706.

When using the melamine compound as the adhesion auxiliary agent, based on 100 parts by weight of the used amount of the polysiloxane (A), the used amount of the melamine compound is from 0 part by weight to 20 parts by weight; preferably from 0.5 parts by weight to 18 parts by weight; and more preferably from 1.0 part by weight to 15 parts by weight.

The silane-based compound is, for example, vinyltrimethoxysilane, vinyltriethoxysilane, 3-acryloxypropyltrimethoxysilane, vinyl tris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropyldimethylmethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, 3-mercaptopropyltrimethoxysilane or a commercially available product manufactured by Shin-Etsu Chemical Company (trade name of KBM403).

When using the silane-based compound as the adhesion auxiliary agent, based on 100 parts by weight of the used amount of the polysiloxane (A), the used amount of the silane-based compound is 0 part by weight to 2 parts by weight; preferably 0.05 parts by weight to 1 part by weight; and more preferably 0.1 parts by weight to 0.8 parts by weight.

The surfactants are, for example, anionic surfactants, cationic surfactants, nonionic surfactants, amphoteric surfactants, polysiloxane-based surfactants, fluorine-based surfactants or a combination thereof.

Examples of the surfactant include (1) polyoxyethylene alkyl ethers: polyoxyethylene lauryl ether, etc.; (2) polyoxyethylene phenyl ethers: polyoxyethylene octyl phenyl ether, polyoxyethylene nonyl phenyl ether, etc.; (3) polyethylene glycol diesters: polyethylene glycol dilaurate, polyethylene glycol distearate, etc.; (4) sorbitan fatty acid esters; and (5) fatty acid modified poly esters; and (6) tertiary amine modified polyurethanes. Commercially available products of surfactant are, for example, KP (manufactured by Shin-Etsu Chemical), SF-8427 (manufactured by Dow Corning Toray Silicone Co., Ltd.), Polyflow (manufactured by Kyoeisha Grease Chemical), F-Top (manufactured by Tochem Products Co., Ltd.), Megaface (manufactured by Dainippon ink chemical industry (DIC)), Fluorade (by Sumitomo 3M Co., Ltd.), Surflon (manufactured by Asahi Glass), SINOPOL E8008 (Sino Japan Chemical Co. Ltd.), F-475 (manufactured by Dainippon ink chemical industry) or combinations thereof.

Based on 100 parts by weight of the used amount of the polysiloxane (A), the used amount of the surfactant is from 0.5 parts by weight to 50 parts by weight; preferably from 1 part by weight to 40 parts by weight; and more preferably from 3 parts by weight to 30 parts by weight.

Examples of the defoamer include Surfynol MD-20, Surfynol MD-30, EnviroGem AD01, EnviroGem AE01, EnviroGem AE02, Surfynol DF110D, Surfynol 104E, Surfynol 420, Surfynol DF37, Surfynol DF58, Surfynol DF66, Surfynol DF70 and Surfynol DF210 (manufactured by Air products) and the like. Based on 100 parts by weight of the used amount of the polysiloxane (A), the used amount of the defoamer is from 1 part by weight to 10 parts by weight; preferably from 2 parts by weight to 9 parts by weight; and more preferably from 3 parts by weight to 8 parts by weight.

Examples of the dissolution promoter include N-hydroxydicarboxylic imide and a compound containing a phenolic hydroxyl group. For example, the dissolution promoter is the compound containing the phenolic hydroxyl group used in the o-naphthoquinone diazide sulfonic acid ester (B). Based on 100 parts by weight of the used amount of the polysiloxane (A), the used amount of the dissolution promoter is from 1 part by weight to 20 parts by weight; preferably from 2 parts by weight to 15 parts by weight; and more preferably from 3 parts by weight to 10 parts by weight.

The photosensitive polysiloxane composition can be prepared in the following manner: placing the polysiloxane (A), the o-naphthoquinone diazide sulfonic acid ester (B), the thermal base generator (C) and the solvent (D) in a blender and stirring them until homogeneously mixed into a solution state. If necessary, the additive (E) can be added.

The present invention also provides a method for forming a thin film on a substrate comprising applying the photosensitive polysiloxane composition as mentioned above on the substrate.

The present invention also provides a thin film on a substrate, which is manufactured by the method as mentioned above.

The present invention further provides a device comprising the thin film. Preferably, the thin film is a planarization film of a TFT substrate in a liquid crystal display element or organic light-emitting display device, an interlayer insulating film or an overcoat of a core material or a protective material in a waveguide.

The following descriptions detail the method of forming the thin film, comprising: using a photosensitive polysiloxane composition to form a pre-baked coating film, pattern-exposing of the pre-baked coating film, removing the unexposed region of the film by an alkali developer to form a pattern, and performing a post-baking treatment to form the thin film.

Forming a Pre-Baked Coating Film

By spin coating, cast coating, or roll coater coating method, the photosensitive polysiloxane composition in the above solution state is coated onto the device to be protected (hereinafter referred to as substrate), to form a coating film.

The above-mentioned substrate can be alkali-free glass, soda lime glass, Pyrex glass, quartz glass, or glasses adhered with a transparent conductive film used in a liquid crystal display device, or a substrate (such as, silicon substrate) used in the photoelectric conversion device (such as a solid-state imaging device).

After forming the coating film, most of the organic solvent of the photosensitive polysiloxane composition is removed by reducing pressure and drying method, and then all the residual organic solvent is removed completely by pre-baking method, to form a pre-baked coating film.

The above-mentioned operation condition can be different according to the kinds of the components and ratio. Generally, reducing pressure and drying are at a pressure of 0 to 200 Torr for 1 second to 60 seconds, and pre-baking is at a temperature between 70° C. to 110° C. for 1 minute to 15 minutes.

Pattern-Exposing

A mask having a specific pattern is used to perform exposure for the above-mentioned pre-baked coating film. The light used in the exposure process, is preferably ultraviolet (UV) rays (g line, b line, i line, etc.), and the device used to provide UV rays can be an ultra high-pressure mercury lamp or a metal halide lamp.

Developing

Unnecessary portions of the above exposed pre-baked coating film are removed by immersing the pre-baked coating film in the developer solution at a temperature between 23±2° C. and developing for about 15 seconds to 5 minutes, so as to form a semi-finished product of the thin film with a predetermined pattern on the substrate. The developer can be alkaline compounds, such as, sodium hydroxide, potassium hydroxide, sodium carbonate, sodium hydrogen carbonate, potassium carbonate, potassium bicarbonate, sodium silicate, sodium methylsilicate, aqueous ammonia, ethylamine, diethylamine, dimethyl ethanolamine, tetramethylammonium hydroxide (THAM), tetraethylammonium hydroxide, choline, pyrrole, piperidine, or 1,8-diaza-bicyclo-(5,4,0)-7-undecene.

It is noted that if the concentration of the developer is too high, the specific pattern may be damaged or the resolution of the specific pattern may be deteriorated. If the concentration of the developer is too low, poor development may happen, and the specific pattern may not be formed or residues of the composition remain in the exposed portions. Therefore, the concentration of the developer affects the formation of the subsequent specific pattern of the photosensitive polysiloxane composition after exposure. The concentration range of the liquid developer is preferably from 0.001 wt % to 10 wt %; more preferably from 0.005 wt % to 5 wt %; further more preferably from 0.01 wt % to 1 wt %. The present embodiment of the present invention employs a developer of 2.38 wt % tetramethylammonium hydroxide. It is noted that even using a lower concentration of the developer, the photosensitive polysiloxane composition of the present invention is capable of forming a fine pattern.

Post-Baking

The substrate (semi-finished product of the thin film with the predetermined pattern on the substrate) is washed with water to remove the unwanted portions of the above-mentioned exposed pre-baked coating film. Then, compressed air or compressed nitrogen is used to dry up the semi-finished product of the thin film with the predetermined pattern. Finally, the semi-finished product of the thin film with the predetermined pattern is post-baked on a heating plate or in an oven. The heating temperature is set between 100° C. to 250° C., and the heating time with the heating plate is 1 to 60 minutes or the heating time with the oven is 5 to 90 minutes. Thereby, the semi-finished product of the thin film with the predetermined pattern is cured to form a thin film.

The present invention will provide more details hereinafter in the following embodiments, but it should be understood that these examples are only illustrative and for illustrative purposes and should not be construed to limit the present invention.

Synthesis of Polysiloxane (A-1)

Following adding 0.30 mole of methyltrimethoxysilane (hereinafter referred to as MTMS), 0.65 mole of phenyltrimethoxysilane (hereinafter referred to as PTMS), 0.05 mole of 3-(triethoxysilyl) propyl succinic anhydride (hereinafter referred to as GF-20) and 200 g of propylene glycol monoethyl ether (hereinafter referred to PGEE) into a 500 ml three-necked flask, an aqueous oxalic acid solution (0.40 g oxalic acid/75 g water) was added at room temperature with stirring within 30 minutes. Next, the flask was immersed at 30° C. in oil bath and stirred for 30 minutes. Then, within 30 minutes, the temperature of the oil bath was raised to 120° C. After the solution temperature was dropped to 105° C., heating was resumed with stirring for polymerization for 6 hours. Then again, the solvent was removed using distillation to obtain the polysiloxane (A-1). The kinds and used amounts of the raw materials of the polysiloxane (A-1) are shown in Table 1.

Synthesis of Polysiloxane (A-2) to (A-5)

Synthesis examples (A-2) to (A-5) were practiced with the analogous method as in Synthesis example (A-1) by using various kinds or amounts of the components of the silane monomer and polysiloxane which are listed in Table 1. The amounts of solvent and oxalic acid, the reaction temperature and the time of polymerization and condensation are different from those of the aforementioned polysiloxane (A-1) which are also listed in Table 1.

TABLE 1

| | Composition | | | | | | | | | | | | | |
|---|---|---|---|---|---|---|---|---|---|---|---|---|---|---|
| | | | | | | | | | | | Catalyst (g) | | | |
| | silane monomer/polysiloxane (mol) | | | | | | | | Solvent (g) | | DI | Oxalic | Temp. | Time |
| Preparation | MTMS | DMDMS | PTMS | PTES | GF-20 | TMSG | TMSOX-D | DMS-S27 | PGEE | DAA | water | acid | (° C.) | (hour) |
| A-1 | 0.30 | | 0.65 | | 0.05 | | | | 200 | | 75 | 0.40 | 105 | 6 |
| A-2 | | 0.40 | 0.40 | 0.15 | 0.03 | | 0.02 | | 100 | 100 | 75 | 0.40 | 110 | 5 |
| A-3 | | 0.60 | 0.35 | | | 0.05 | | | 200 | | 75 | 0.35 | 105 | 6 |
| A-4 | 0.65 | | | 0.25 | | | 0.09 | 0.01 | 200 | | 75 | 0.45 | 110 | 6 |
| A-5 | 0.65 | | 0.35 | | | | | | 200 | | 75 | 0.45 | 110 | 6 |

| | | MW |
|---|---|---|
| MTMS | methyltrimethoxysilane | 136 |
| DMDMS | dimethyldimethoxysilane | 120 |
| PTMS | phenyltrimethoxysilane | 198 |
| PTES | phenyltriethoxysilane | 240 |
| GF-20 | 3-(triethoxysilyl)propyl succinic anhydride | 304 |
| TMSG | 3-(trimethoxysilyl)propyl glutaric anhydride | 276 |
| TMSOX-D | 2-oxetanylbutoxypropyltrimethoxysilane | 278 |
| DMS-S27 | the silanol end portion of polysiloxane(manufactured by Gelest Co., Ltd.) | 18000 |
| PGEE | propylene glycol monoethyl ether | 104 |
| DAA | diacetone alcohol | 116 |
| DI water | | 18 |
| Oxalic acid | | 90 |

### EXAMPLE 1

One-hundred parts by weight of the used amount of the polysiloxane (A-1), 1 part by weight of the ortho-naphthoquinone diazide sulfonic acid ester (B-1) formed from 1-[1-(4-hydroxyphenyl) isopropyl]-4-[1,1-bis(4-hydroxyphenyl) ethyl]benzene and ortho-naphthoquinone diazide-5-sulfonic acid, and 0.05 parts by weight of 1,5-diazabicyclo[4.3.0]non-5-ene (DBN) (C-1) were mixed and dissolved in 100 parts by weight of the propylene glycol monomethyl ether acetate (D-1) completely, so as to form the photosensitive polysiloxane composition of Example 1.

Formation of Thin Film on Glass

Various photosensitive polysiloxane compositions were cast coated independently on a prime glass substrate of 100×100×0.7 mm in size, and then pre-baked for 2 minutes at 100° C. to obtain a pre-baked coating film of about 2 μm in thickness. And then, the pre-baked coating film was placed under the light mask with a given pattern, and ultraviolet light of 100 mJ/cm² was used to irradiate the film. Afterwards, the exposed coating film was immersed in 2.38% TMAH solution for 60 seconds at 23° C. to remove the unexposed parts, and then the film was washed with pure water; and placed under the light mask with the given pattern, and exposed with the ultraviolet light of 200 mJ/cm². Finally, the film was post-baked for 60 minutes at 230° C., so as to form the film on the prime glass substrate.

The evaluation results of the thin film of Example 1 are shown in Table 2.

### EXAMPLES 2 TO 8 AND COMPARATIVE EXAMPLES 1 to 3

Examples 2 to 8 and Comparative Examples 1 to 3 were practiced with the same method as in Example 1 by using various kinds or amounts of the components, the formulas. The evaluation results of which are also listed in Table 2.

Evaluation

Chemical Resistance

Various photosensitive polysiloxane compositions were spin coated independently on a prime glass substrate of 100×100×0.7 mm³ in size to obtain a pre-baked coating film of about 2 μm in thickness, and then pre-baked for 2 minutes at 110° C. And then, the pre-baked coating film was placed under the light mask with a given pattern, and ultraviolet light of 100 mJ/cm² was used to irradiate the film. Afterwards, the exposed coating film was immersed in 2.38% tetramethylammonium hydroxide solution for 60 seconds to remove the exposed parts, and then the film was washed with pure water; and placed under the light mask with the given pattern, and exposed with the ultraviolet light of 200 mJ/cm². And then, the film was post-baked at different time at 230° C. Afterwards, the post-baked film was immersed in TOK106 solution for 6 minutes at 60° C., and film thickness change rate is evaluated by the following Formula:

Film Thickness Change Rate=[(thickness after immersed−thickness before immersed)/thickness before immersed]×100%

preferable film thickness change rate is form −3%˜3%.

©: 3% □ film thickness change rate □−3%,

∘: 5% □ film thickness change rate>3% or −3%>film thickness change rate □−5%,

X: film thickness change rate>5% or film thickness change rate<−5%.

TABLE 2

| | | | | | | | | | | Comparative | | |
|---|---|---|---|---|---|---|---|---|---|---|---|---|
| | | Example | | | | | | | | Example | | |
| Composition | | 1 | 2 | 3 | 4 | 5 | 6 | 7 | 8 | 1 | 2 | 3 |
| polysiloxane (A) | A-1 | 100 | | | | 100 | | | | 100 | | |
| (parts by weight) | A-2 | | 100 | | | | 80 | | 30 | | | |
| | A-3 | | | 100 | | | | 50 | | | | |
| | A-4 | | | | 100 | | | 50 | 70 | | | |
| | A-5 | | | | | | 20 | | | | 100 | 100 |
| o-naphthoquinone | B-1 | 1 | 5 | 10 | 10 | | 30 | 10 | 20 | 20 | | 15 |
| diazide sulfonic | B-2 | | | | 5 | 20 | | 10 | | | 20 | |
| acid ester (B) | | | | | | | | | | | | |
| (parts by weight) | | | | | | | | | | | | |
| thermal base | C-1 | 0.05 | | | | | 10 | | | | | |
| generator (C) | C-2 | | 0.1 | | | | | | | | | |
| (parts by weight) | C-3 | | | | | | | 5 | | | 5 | |
| | C-4 | | | | 5 | | 10 | | | | | |
| | C-5 | | | | | 10 | | | | | | |
| | C-6 | | | 1 | | | | | | | | |
| | C-7 | | | | | | | 5 | | | | |
| | C-8 | | | | | | | | 15 | | | |
| Solvent (D) | D-1 | 100 | | 500 | | 300 | 500 | 1000 | | 500 | | 500 |
| (parts by weight) | D-2 | | 300 | | 500 | | 300 | | | | 500 | |
| | D-3 | | | | | | | 200 | 500 | | | |
| additive (E) | E-1 | | | | 3 | | | | | | | |
| (parts by weight) | E-2 | | | | | | | 0.5 | | | | |
| Evaluation | Chemical | ◯ | ◯ | ◯ | ◯ | ◯ | ◯ | ◯ | ◯ | X | X | X |
| | Resistance | | | | | | | | | | | |

B-1 ortho-naphthoquinone diazide sulfonic acid ester formed from 1-[1-(4-hydroxyphenyl)isopropyl]-4-[1,1-bis(4-hydroxyphenyl)ethyl] benzene and ortho-naphthoquinone diazide-5-sulfonic acid
B-2 ortho-naphthoquinone diazide sulfonic acid ester formed from 2,3,4-trihydroxy-benzophenone and ortho-naphthoquinone diazide-5-sulfonic acid
C-1 1,5-diazabicyclo[4.3.0]non-5-ene (DBN)
C-2 U-CAT ® SA851
C-3 U-CAT ® 5002
C-4 N-(isopropoxycarbonyl)-2,6-dimethyl piperidine
C-5 N-(1-ethylpropoxycarbonyl) diisopropylamine
C-6 N-(cyclopentyloxycarbonyl)-2,6-dimethyl piperidine
C-7 N-(benzyloxycarbonyl) pyrrolidine
C-8 1,4-bis (N,N′-diisopropylaminecarbonyl) cyclohexane
D-1 propylene glycol monomethyl ether acetate
D-2 4-hydroxy-4-methyl-2-pentanone
D-3 cyclohexanone
E-1 SF-8427 (manufactured by Dow Corning Toray Silicone Co., Ltd., surfactant)
E-2 3-glycidoxypropyl trimethoxy silane (trade name of KBM403, manufactured by Shin-Etsu Chemical Company, adhesion auxiliary agent)

While embodiments of the present invention have been illustrated and described, various modifications and improvements can be made by persons skilled in the art. It is intended that the present invention is not limited to the particular forms as illustrated, and that all modifications not departing from the spirit and scope of the present invention are within the scope as defined in the following claims.

What is claimed is:

1. A photosensitive polysiloxane composition comprising:
a polysiloxane (A);
an o-naphthoquinone diazide sulfonic acid ester (B);
a thermal base generator (C); and
a solvent (D);
wherein:
the thermal base generator (C) comprises a compound represented by Formula (1) or an salt derivative thereof and/or a compound represented by Formula (2) and/or a compound represented by Formula (3): 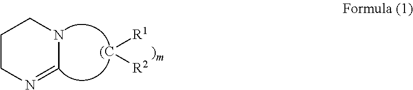
wherein:
m represents an integer selected from 2 to 6;
R¹ and R² independently represent a hydrogen atom, a C₁-C₈ alkyl group, a substituted or unsubstituted C₁-C₆ hydroxyalkyl group, or a C₂-C₁₂ dialkylamino group; 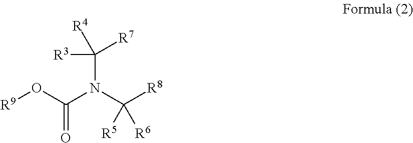
wherein:
R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;
R⁷ and R⁸ independently represent a hydrogen atom, a substituted or unsubstituted C₁-C₈ alkyl group, a substituted or unsubstituted C₃-C₈ cylcoalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group;
R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12; 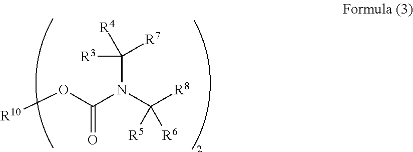
wherein:
R³, R⁴, R⁵, R⁶, R⁷ and R⁸ are as defined in Formula (2);
R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsbustituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

2. The photosensitive polysiloxane composition according to claim 1, wherein the polysiloxane (A) is a copolymer obtained by hydrolyzing and partial condensing a silane monomer component represented by Formula (4);
Si(Rₐ)_{W}(OR_{b})_{4-w} Formula (4),
wherein:
at least one of Rₐ represents an alkyl group substituted with an acid anhydride group, an alkyl group substituted with an epoxy group and/or an alkoxy group substituted with an epoxy group; other Rₐ represents a hydrogen atom, a C₁-C₁₀ alkyl group, a C₂-C₁₀ alkenyl group, a C₆-C₁₅ aryl group; each Rₐ is the same or different;
R_{b} represents a hydrogen atom, a C₁-C₆ alkyl group, a C₁-C₆ acyl group, a C₆-C₁₅ aryl group; each R_{b} is the same or different; and
w represents an integer from 0 to 3.

3. The photosensitive polysiloxane composition according to claim 1, wherein based on 100 parts by weight of the used amount of the polysiloxane (A), the used amount of the o-naphthoquinone diazide sulfonic acid ester (B) is from 1 part by weight to 30 parts by weight.

4. The photosensitive polysiloxane composition according to claim 1, wherein based on 100 parts by weight of the used amount of the polysiloxane (A), the used amount of the thermal base generator (C) is from 0.05 parts by weight to 20 parts by weight.

5. The photosensitive polysiloxane composition according to claim 1, wherein based on 100 parts by weight of the used amount of the polysiloxane (A), the used amount of the solvent (D) is from 100 parts by weight to 1200 parts by weight.

6. A method for forming a thin film on a substrate comprising applying the photosensitive polysiloxane composition according to claim 1 on the substrate.

7. The method according to claim 6, wherein the polysiloxane (A) is a copolymer obtained by hydrolyzing and partial condensing a silane monomer component represented by Formula (4);
Si(Rₐ)_{W}(OR_{b})_{4-w} Formula (4),
wherein:
at least one of Rₐ represents an alkyl group substituted with an acid anhydride group, an alkyl group substituted with an epoxy group and/or an alkoxy group substituted with an epoxy group; other Rₐ represents a hydrogen atom, a C₁-C₁₀ alkyl group, a C₂-C₁₀ alkenyl group, a C₆-C₁₅ aryl group; each Rₐ is the same or different;
R_{b} represents a hydrogen atom, a C₁-C₆ alkyl group, a C₁-C₆ acyl group, a C₆-C₁₅ aryl group; each R_{b} is the same or different; and
w represents an integer from 0 to 3.

8. The method according to claim 6, wherein based on 100 parts by weight of the used amount of the polysiloxane (A), the used amount of the o-naphthoquinone diazide sulfonic acid ester (B) is from 1 part by weight to 30 parts by weight.

9. The method according to claim 6, wherein based on 100 parts by weight of the used amount of the polysiloxane (A), the used amount of the thermal base generator (C) is from 0.05 parts by weight to 20 parts by weight.

10. The method according to claim 6, wherein based on 100 parts by weight of the used amount of the polysiloxane (A), the used amount of the solvent (D) is from 100 parts by weight to 1200 parts by weight.

11. A thin film on a substrate, which is manufactured by the method according to claim 6.

12. The thin film according to claim 11, wherein the polysiloxane (A) is a copolymer obtained by hydrolyzing and partial condensing a silane monomer component represented by Formula (4);
Si(Rₐ)_{W}(OR_{b})_{4-w} Formula (4),
wherein:
at least one of Rₐ represents an alkyl group substituted with an acid anhydride group, an alkyl group substituted with an epoxy group and/or an alkoxy group substituted with an epoxy group; other Rₐ represents a hydrogen atom, a C₁-C₁₀ alkyl group, a C₂-C₁₀ alkenyl group, a C₆-C₁₅ aryl group; each Rₐ is the same or different;
R_{b} represents a hydrogen atom, a C₁-C₆ alkyl group, a C₁-C₆ acyl group, a C₆-C₁₅ aryl group; each R_{b} is the same or different; and
w represents an integer from 0 to 3.

13. The thin film according to claim 11, wherein based on 100 parts by weight of the used amount of the polysiloxane (A), the used amount of the o-naphthoquinone diazide sulfonic acid ester (B) is from 1 part by weight to 30 parts by weight.

14. The thin film according to claim 11, wherein based on 100 parts by weight of the used amount of the polysiloxane (A), the used amount of the thermal base generator (C) is from 0.05 parts by weight to 20 parts by weight.

15. The thin film according to claim 11, wherein based on 100 parts by weight of the used amount of the polysiloxane (A), the used amount of the solvent (D) is from 100 parts by weight to 1200 parts by weight.

16. The thin film according to claim 11, wherein the thin film is a planarization film of a TFT substrate in a liquid crystal display element or organic light-emitting display device, an interlayer insulating film or an overcoat of a core material or a protective material in a waveguide.

17. A device comprising the thin film according to claim 11.

18. The device according to claim 17, wherein the thin film is a planarization film of a TFT substrate in a liquid crystal display element or organic light-emitting display device, an interlayer insulating film or an overcoat of a core material or a protective material in a waveguide.
